(19) United States
(12) Patent Application Publication
(10) Pub. No.: US 2025/0008645 A1
(43) Pub. Date: Jan. 2, 2025

(54) PRINTED WIRING BOARD

(71) Applicant: IBIDEN CO., LTD., Ogaki (JP)

(72) Inventor: Youhong WU, Ogaki (JP)

(73) Assignee: IBIDEN CO., LTD., Ogaki (JP)

(21) Appl. No.: 18/753,385

(22) Filed: Jun. 25, 2024

(30) Foreign Application Priority Data
Jun. 27, 2023 (JP) 2023-105255

(51) Int. Cl. H05K 1/02; H05K 1/05; H05K 3/46

(52) U.S. Cl. CPC H05K 1/0298; H05K 1/053; H05K 3/467; H05K 2201/0209; H05K 2201/0212; H05K 2201/0338

(57) ABSTRACT

A printed wiring board includes a first resin insulating layer, a first conductor layer formed on the first insulating layer, a second resin insulating layer formed on the first conductor layer, a second conductor layer formed on the second insulating layer, and a via conductor formed in the second insulating layer such that the via conductor is connecting the first conductor layer and second conductor layer. The second conductor layer includes a seed layer formed on the second insulating layer and an electrolytic plating film on the seed layer such that the seed layer includes a first film formed in contact with the second insulating layer and a second film formed on the first film, and the seed layer in the second conductor layer is formed such that the first film includes an alloy including copper, titanium and impurities including carbon, oxygen, and silicon and the second film includes copper.

### CROSS-REFERENCE TO RELATED APPLICATIONS

The present application is based upon and claims the benefit of priority to Japanese Patent Application No. 2023-105255, filed Jun. 27, 2023, the entire contents of which are incorporated herein by reference.

### BACKGROUND OF THE INVENTION

### Field of the Invention

The present invention relates to a printed wiring board.

### Description of Background Art

Japanese Patent Application Laid-Open Publication No. 2000-124602 describes a printed wiring board having a resin substrate, a resin insulating layer formed on the resin substrate, and a conductor circuit. The entire contents of this publication are incorporated herein by reference.

### SUMMARY OF THE INVENTION

According to one aspect of the present invention, a printed wiring board includes a first resin insulating layer, a first conductor layer formed on the first resin insulating layer, a second resin insulating layer formed on the first conductor layer, a second conductor layer formed on the second resin insulating layer, and a via conductor formed in the second resin insulating layer such that the via conductor is connecting the first conductor layer and the second conductor layer. The second conductor layer includes a seed layer formed on the second resin insulating layer and an electrolytic plating film on the seed layer such that the seed layer includes a first film formed in contact with the second resin insulating layer and a second film formed on the first film, and the seed layer in the second conductor layer is formed such that the first film includes an alloy including copper, titanium and impurities including carbon, oxygen, and silicon and that the second film includes copper.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view schematically illustrating a printed wiring board according to an embodiment of the present invention;

FIG. 1B is a cross-sectional view schematically illustrating a method for manufacturing a printed wiring board according to an embodiment of the present invention;

FIG. 1C is a cross-sectional view schematically illustrating a method for manufacturing a printed wiring board according to an embodiment of the present invention;

FIG. 1D is a cross-sectional view schematically illustrating a method for manufacturing a printed wiring board according to an embodiment of the present invention;

FIG. 1E is a cross-sectional view schematically illustrating a method for manufacturing a printed wiring board according to an embodiment of the present invention;

FIG. 2A is a cross-sectional view schematically illustrating a method for manufacturing a printed wiring board according to an embodiment of the present invention;

FIG. 2B is a cross-sectional view schematically illustrating a method for manufacturing a printed wiring board according to an embodiment of the present invention;

FIG. 2C is a cross-sectional view schematically illustrating a method for manufacturing a printed wiring board according to an embodiment of the present invention;

FIG. 2D is a cross-sectional view schematically illustrating a method for manufacturing a printed wiring board according to an embodiment of the present invention;

FIG. 2E is a cross-sectional view schematically illustrating a method for manufacturing a printed wiring board according to an embodiment of the present invention;

FIG. 3A is a cross-sectional view schematically illustrating a method for manufacturing a printed wiring board according to an embodiment of the present invention;

FIG. 3B is a cross-sectional view schematically illustrating a method for manufacturing a printed wiring board according to an embodiment of the present invention;

FIG. 3C is a cross-sectional view schematically illustrating a method for manufacturing a printed wiring board according to an embodiment of the present invention;

FIG. 3D is a cross-sectional view schematically illustrating a method for manufacturing a printed wiring board according to an embodiment of the present invention;

FIG. 4A is a cross-sectional view schematically illustrating a method for manufacturing a printed wiring board according to an embodiment of the present invention;

FIG. 4B is a cross-sectional view schematically illustrating a method for manufacturing a printed wiring board according to an embodiment of the present invention;

FIG. 4C is a cross-sectional view schematically illustrating a method for manufacturing a printed wiring board according to an embodiment of the present invention; and

FIG. 4D is a cross-sectional view schematically illustrating a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Printed Wiring Board

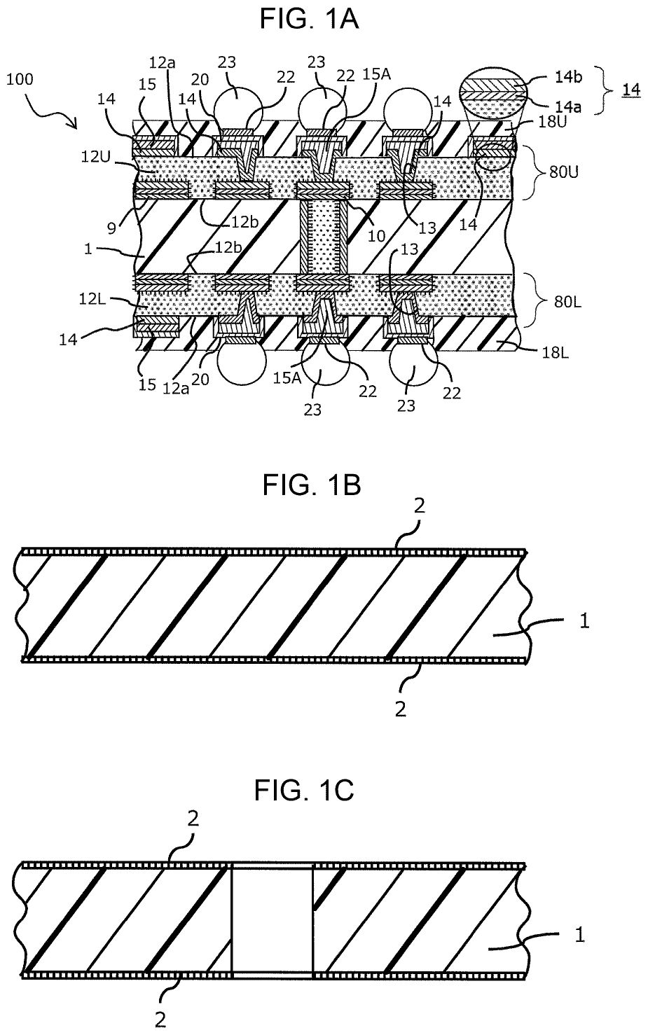

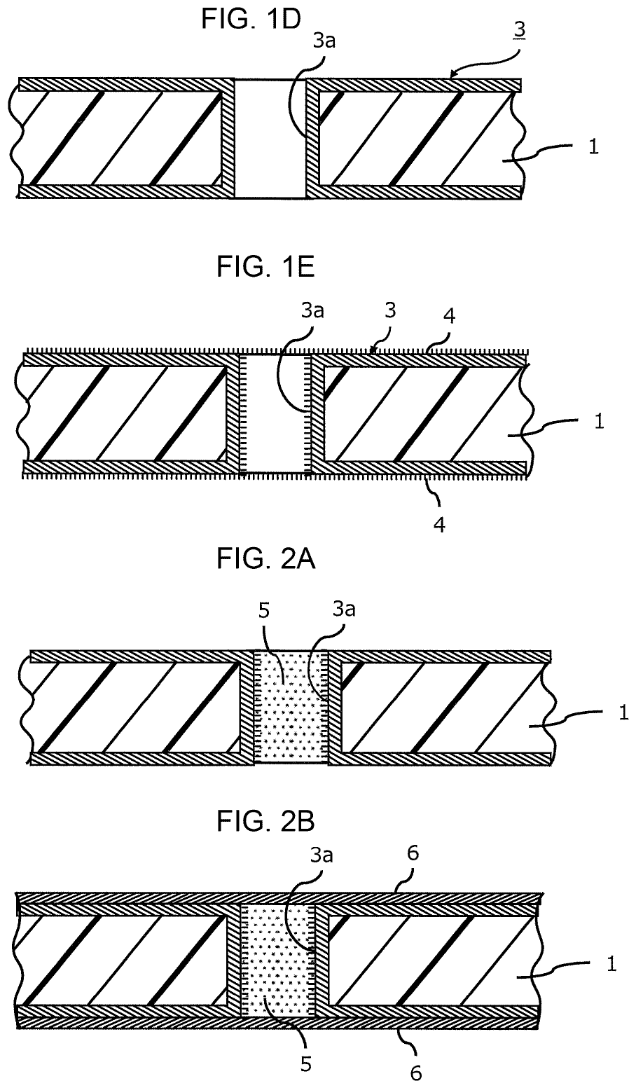

FIG. 1A is a cross-sectional view of a printed wiring board 100 according to an embodiment of the present invention. As illustrated in FIG. 1, the printed wiring board 100 has a substrate 1 and build-up layers (80U, 80L) formed on both front and back sides of the substrate 1. A first conductor layer formed of a lower-layer conductor circuit 9 and a conductor layer 10 is formed on the substrate 1.

The build-up layers (80U, 80L) are each formed of a resin insulating layer (12U, 12L), a second conductor layer formed of a seed layer 14 and an electrolytic copper plating film 15 (electrolytic plating film) on the seed layer 14, and via conductors (15A) that penetrate the resin insulating layer (12U, 12L) to connect adjacent conductor layers. The resin insulating layer (12U, 12L) is a second resin insulating layer. The resin insulating layer (12U, 12L) has via conductor openings 13 that reach the lower-layer conductor circuit 9 and the conductor layer 10. The resin insulating layer (12U, 12L) contains glass particles. The resin insulating layer (12U, 12L) contains carbon, oxygen, and silicon.

The seed layer 14 is formed of a Cu/Ti alloy layer (14a) (first film) in contact with the resin insulating layer (12U, 12L) and a Cu layer (14b) (second film) on the Cu/Ti alloy layer (14a).

The Cu/Ti alloy layer (14a) is formed of an alloy containing copper and titanium. The alloy contains carbon, oxygen, and silicon as impurities. A content of carbon in the alloy is 0.05 at % or more and 25 at % or less. A content of oxygen in the alloy is 0.05 at % or more and 25 at % or less. A content of silicon in the alloy is 0.05 at % or more and 3 at % or less. A content of copper in the alloy is 50 at % or more and 90 at % or less. A content of titanium in the alloy is 1 at % or more and 30 at % or less. The Cu/Ti alloy layer (14a) has a thickness of 10 nm or more and 500 nm or less.

The Cu layer (14b) is formed of copper. The Cu layer (14b) has a thickness of 100 nm or more and 500 nm or less.

The second conductor layer includes multiple conductor circuits. Among the multiple conductor circuit widths, a conductor circuit having a smallest width (smallest conductor circuit) has a width of 1.5 μm or more and 5 μm or less.

The Cu/Ti alloy layer (14a) in contact with the resin insulating layer (12U, 12L) is formed of an alloy containing copper and titanium, and the alloy contains carbon, oxygen, and silicon as impurities. Therefore, it has strong adhesion to the resin insulating layer (12U, 12L) that contains carbon, oxygen, and silicon. The adhesion between the Cu/Ti alloy layer (14a) and the resin insulating layer (12U, 12L) is high. Therefore, even when the conductor circuits of the second conductor layer have small widths, the conductor circuits are unlikely to peel off from the resin insulating layer (12U, 12L).

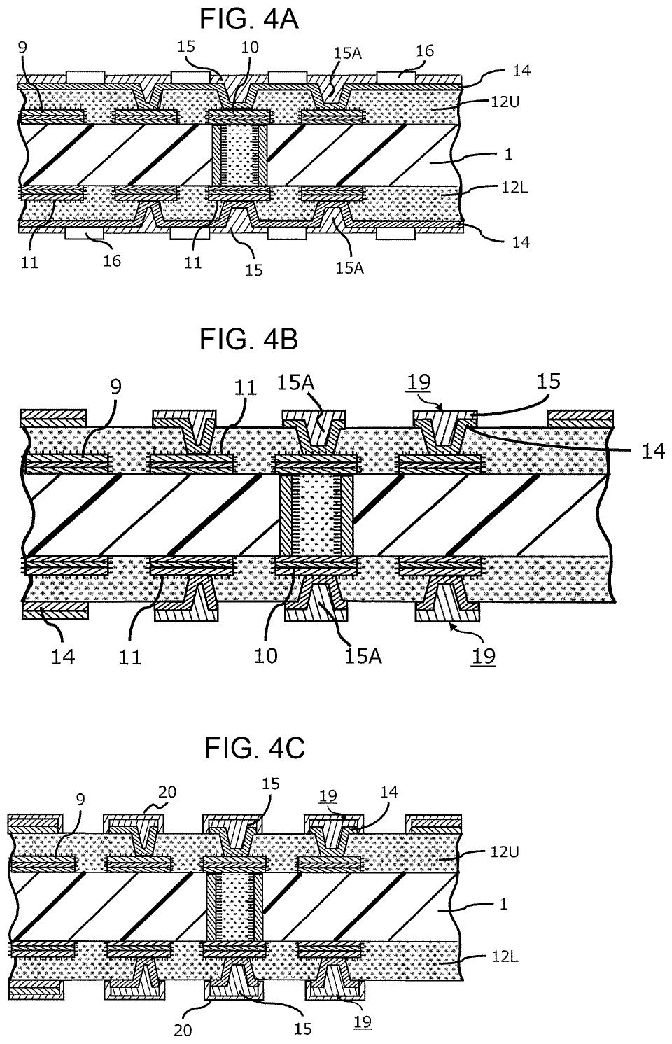

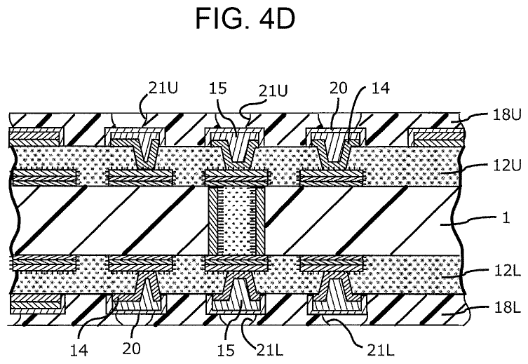

FIG. 1A omits a multi-layering process to be described later and illustrates a state in which the build-up layers (80U, 80L) each formed of the resin insulating layer (12U, 12L), the second conductor layer, and the via conductors (15A) are formed on the substrate 1 having upper-layer conductor circuits 19 and the like formed in FIG. 4C to be described later. Actually, through the multi-layering process, in each of the build-up layers (80U, 80L), a second-to-outermost resin insulating layer (first resin insulating layer) is laminated on an inner-layer side of an outermost resin insulating layer (second resin insulating layer). A conductor layer (first conductor layer) is formed on the second-to-outermost resin insulating layer. The outermost resin insulating layer is formed on the second-to-outermost resin insulating layer and the first conductor layer. The conductor layer (second conductor layer) formed on the outermost resin insulating layer and the conductor layer (first conductor layer) formed on the second-to-outermost resin insulating layer are connected by via conductors formed in via conductor openings reaching the first conductor layer.

The printed wiring board 100 has a solder resist pattern layer (18U, 18L) on each of the build-up layers (80U, 80L). The solder resist pattern layer (18U, 18L) has openings (21U, 21L). The second conductor layer exposed by the openings (21U, 21L) functions as pads for mounting an electronic component. Solder bumps 23 for mounting the electronic component are formed on the pads.

### Method for Manufacturing Printed Wiring Board

FIGS. 1B-4D illustrate a method for manufacturing a printed wiring board according to an embodiment of the present invention. FIGS. 1B-4G are cross-sectional views.

As illustrated in FIG. 1B, a copper-clad laminated plate with a copper foil 2 adhered to both sides of the substrate 1 is used as a starting material. As illustrated in FIG. 1C, the copper-clad laminate is drilled to form a through hole for a through-hole conductor. After that, electroless plating is performed to form an electroless plating film over an entire surface of the substrate 1. Further, electrolytic copper plating is performed to form an electrolytic copper plating film. As illustrated in FIG. 1D, a conductor layer 3, including a through-hole conductor (3a), is formed on the entire surface of the substrate 1.

The substrate 1, on which the conductor layer 3 is formed, is washed with water and then dried. After that, the substrate 1 is subjected to a redox treatment using an oxidation bath (blackening bath) containing a predetermined aqueous solution, and a reduction bath. As illustrated in FIG. 1E, a roughened surface 4 is formed on the entire surface of the conductor layer 3 including the through-hole conductor (3a).

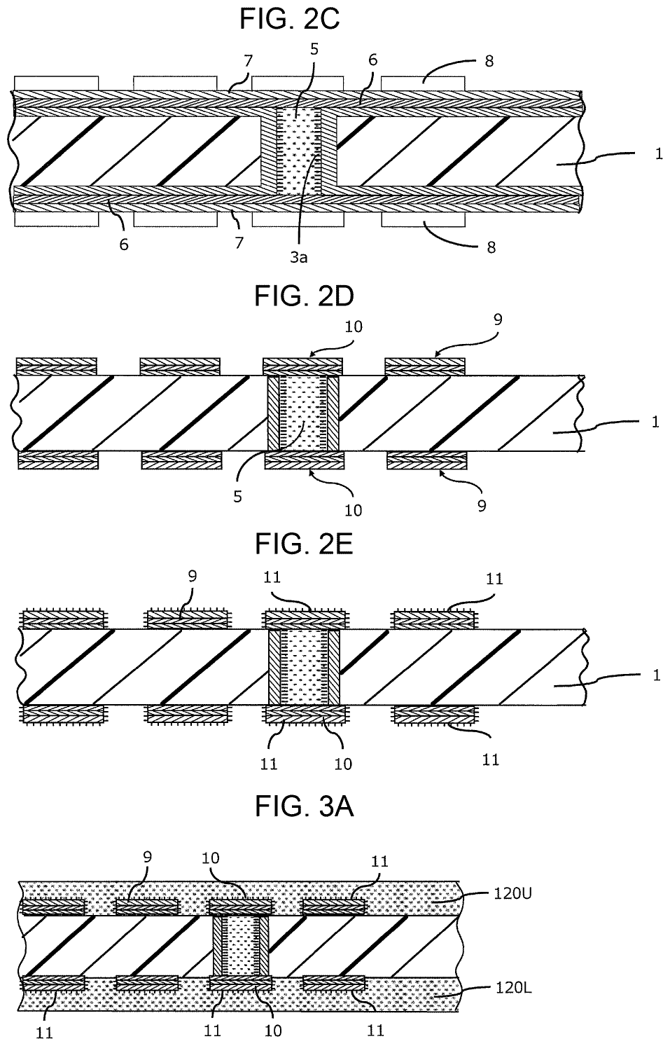

As illustrated in FIG. 2A, a metal particle paste 5 containing copper particles is filled into the through-hole conductor (3a) by screen printing, and then dried and cured. After that, the roughened surface 4 formed on the surface of the conductor layer 3 and the metal particle paste 5 protruding from the through-hole conductor (3a) are removed by polishing, and the surface of the substrate 1 is flattened.

As illustrated in FIG. 2B, an electroless copper plating film 6 is formed on the flattened surface of the substrate 1 by electroless plating.

After that, electrolytic copper plating is performed under a predetermined condition to form an electrolytic copper plating film 7, and, in a process illustrated in FIG. 2D to be described later, a portion that will become the lower-layer conductor circuit 9 is thickened and a portion that will become the conductor layer 10 that covers the metal particle paste 5 filled in the through-hole conductor (3a), is formed.

As illustrated in FIG. 2C, a photosensitive dry film is applied to both sides of the substrate 1, where portions that will become the lower-layer conductor circuit 9 and the conductor layer 10 are formed. After placing a mask and performing exposure, a development process is carried out to form an etching resist 8.

As illustrated in FIG. 2D, the plating films in areas where the etching resist 8 is not formed are dissolved and removed by etching. After that, the etching resist 8 is peeled off and removed, to form the separate lower-layer conductor circuit 9 and conductor layer 10.

As illustrated in FIG. 2E, a roughened layer 11 is formed on surfaces of the lower-layer conductor circuit 9 and the conductor layer 10, and a Sn layer (not illustrated) is further formed on a surface of the roughened layer 11.

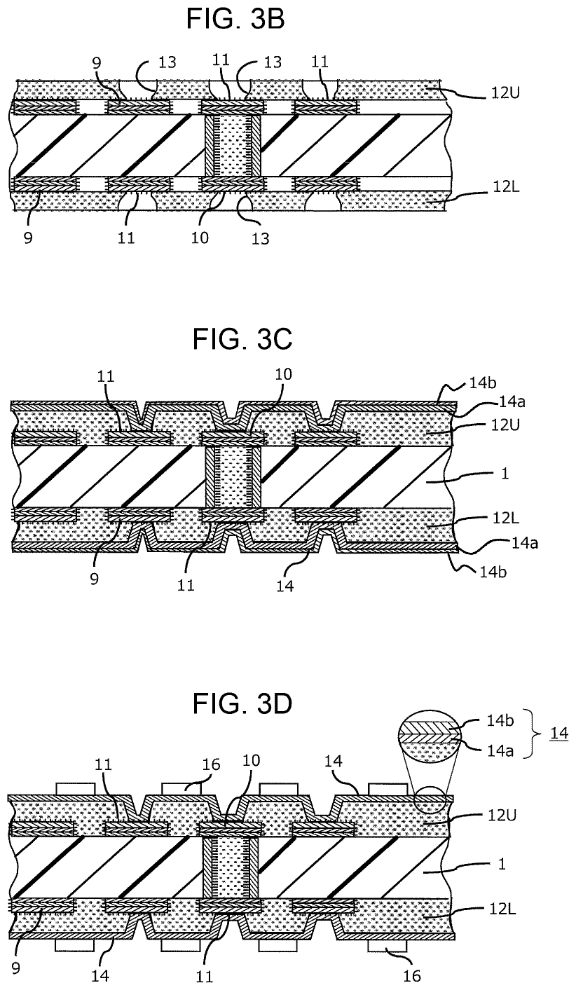

As illustrated in FIG. 3A, an epoxy resin composition is applied to both sides of the substrate 1 to form resin layers (120U, 120L) that will become the resin insulating layers (12U, 12L).

As illustrated in FIG. 3B, after the formation of the resin layers (120U, 120L), ultraviolet exposure and a development process are appropriately carried out to form via conductor openings 13. Further, thermal curing is performed to form the resin insulating layers (12U, 12L).

As illustrated in FIG. 3C, the Cu/Ti alloy layer (14a) is formed on the resin insulating layer (12U, 12L), the via conductor openings 13, the lower-layer conductor circuit 9, and the conductor layer 10 by predetermined sputtering. Further, the Cu layer (14b) is formed by predetermined sputtering. The alloy layer (14a) and the Cu layer (14b) are thin films and both are difficult to be clearly illustrated, so they are collectively denoted using the reference numeral symbol “14” and referred to as the “seed layer 14.”

As illustrated in FIG. 3D, a photosensitive dry film is applied to both sides of the substrate 1, where the Cu layer (14b) is formed. After placing a photo mask film and performing exposure, a development process is carried out to form patterns of a plating resist 16.

As illustrated in FIG. 4A, electrolytic plating is performed under a predetermined condition to form the electrolytic copper plating film 15. By the electrolytic copper plating film 15, thickening of a lower-layer conductor circuit 9 portion and filling-with-plating of a via hole portion are performed (see FIG. 4B to be described later). The via conductors (15A) are formed by the via hole portion of the electrolytic copper plating film 15.

As illustrated in FIG. 4B, after peeling off and removing the plating resist 16, the seed layer 14 underneath the plating resist 16 is removed by etching. The upper-layer conductor circuit 19, formed of the seed layer 14 and the electrolytic copper plating film 15, which includes the via conductors (15A), is formed.

As illustrated in FIG. 4C, predetermined sputtering is performed on the substrate 1 on which the upper-layer conductor circuit 19 is formed, and an alloy layer 20 formed of Ni—Sn is formed on the surface of the upper-layer conductor circuit 19. After that, multi-layering is performed by repeating the processes of FIGS. 3A-4C.

On both sides of the substrate 1, a suitable solder resist composition is applied by coating and then a drying process is carried out. After that, a photomask with a pattern of solder resist openings is adhered to the solder resist layer, and ultraviolet exposure and a development process are carried out to form the openings. Further, by carrying out a heat treatment under a predetermined condition to cure the solder resist layer, the solder resist pattern layers (18U, 18L) having the openings (21U, 21L) are formed, as illustrated in FIG. 4D.

The substrate 1, on which the solder resist pattern layers (18U, 18L) are formed, is immersed in a predetermined electroless plating solution, and a gold plating layer 22 is formed on a nickel plating layer. After that, solder paste is printed in the openings (21U, 21L) of the solder resist pattern layers (18U, 18L), and solder bumps 23 are formed by reflow. The printed wiring board 100 of the embodiment is obtained (see FIG. 1A).

Japanese Patent Application Laid-Open Publication No. 2000-124602 describes a printed wiring board having a resin substrate, a resin insulating layer formed on the resin substrate, and a conductor circuit. The conductor circuit is formed on the resin insulating layer via an alloy layer containing a specific metal. For example, the specific metal is shown in paragraph of Japanese Patent Application Laid-Open Publication No. 2000-124602.

In the printed wiring board having the alloy layer of Japanese Patent Application Laid-Open Publication No. 2000-124602, it is thought that, when the width of the conductor circuit becomes small, the conductor circuit peels off from the resin insulating layer.

A printed wiring board according to an embodiment of the present invention includes: a first resin insulating layer; a first conductor layer that is formed on the first resin insulating layer; a second resin insulating layer that is formed on the first resin insulating layer and the first conductor layer, and has a via conductor opening reaching the first conductor layer; a second conductor layer that is formed on the second resin insulating layer; and a via conductor that is formed in the opening and connects the first conductor layer and the second conductor layer. The second conductor layer is formed of a seed layer on the second resin insulating layer and an electrolytic plating film on the seed layer. The seed layer is formed of a first film in contact with the second resin insulating layer and a second film on the first film. The first film is formed of an alloy containing copper and titanium. The alloy contains carbon, oxygen, and silicon as impurities. The second film is formed of copper.

In the printed wiring board according to an embodiment of the present invention, the first film in contact with the second resin insulating layer is formed of an alloy containing copper and titanium. The alloy contains carbon, oxygen, and silicon as impurities. Therefore, it has strong adhesion to the second resin insulating layer that contains carbon, oxygen, and silicon. The adhesion between the first film and the second resin insulating layer is high. Therefore, even when the conductor circuit has a small width, it is unlikely to peel off from the second resin insulating layer.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a first resin insulating layer;
a first conductor layer formed on the first resin insulating layer;
a second resin insulating layer formed on the first conductor layer;
a second conductor layer formed on the second resin insulating layer; and
a via conductor formed in the second resin insulating layer such that the via conductor is connecting the first conductor layer and the second conductor layer,
wherein the second conductor layer includes a seed layer formed on the second resin insulating layer and an electrolytic plating film on the seed layer such that the seed layer includes a first film formed in contact with the second resin insulating layer and a second film formed on the first film, and the seed layer in the second conductor layer is formed such that the first film includes an alloy comprising copper, titanium and impurities including carbon, oxygen, and silicon and that the second film includes copper.

2. The printed wiring board according to claim 1, wherein the seed layer in the second conductor layer is formed such that the first film and the second film are formed by sputtering.

3. The printed wiring board according to claim 1, wherein the seed layer in the second conductor layer is formed such that the first film has a thickness in a range of 10 nm to 500 nm and that the second film has a thickness in a range of 100 nm to 500 nm.

4. The printed wiring board according to claim 1, wherein the seed layer in the second conductor layer is formed such that the alloy of the first film has a content of the carbon is in a range of 0.05 at % to 25 at %, a content of the oxygen in a range of 0.05 at % to 25 at %, a content of the silicon in a range of 0.05 at % to 3 at %, a content of the copper in a range of 50 at % to 90 at %, and a content of the titanium in a range of 1 at % to 30 at %.

5. The printed wiring board according to claim 1, wherein the second resin insulating layer includes glass particles.

6. The printed wiring board according to claim 5, wherein the second resin insulating layer includes carbon, oxygen and silicon.

7. The printed wiring board according to claim 1, wherein the second conductor layer includes a plurality of conductor circuits including a smallest conductor circuit having a smallest width in a range of 1.5 μm to 5 μm.

8. The printed wiring board according to claim 2, wherein the seed layer in the second conductor layer is formed such that the first film has a thickness in a range of 10 nm to 500 nm and that the second film has a thickness in a range of 100 nm to 500 nm.

9. The printed wiring board according to claim 2, wherein the seed layer in the second conductor layer is formed such that the alloy of the first film has a content of the carbon is in a range of 0.05 at % to 25 at %, a content of the oxygen in a range of 0.05 at % to 25 at %, a content of the silicon in a range of 0.05 at % to 3 at %, a content of the copper in a range of 50 at % to 90 at %, and a content of the titanium in a range of 1 at % to 30 at %.

10. The printed wiring board according to claim 2, wherein the second resin insulating layer includes glass particles.

11. The printed wiring board according to claim 10, wherein the second resin insulating layer includes carbon, oxygen and silicon.

12. The printed wiring board according to claim 2, wherein the second conductor layer includes a plurality of conductor circuits including a smallest conductor circuit having a smallest width in a range of 1.5 μm to 5 μm.

13. The printed wiring board according to claim 3, wherein the seed layer in the second conductor layer is formed such that the alloy of the first film has a content of the carbon is in a range of 0.05 at % to 25 at %, a content of the oxygen in a range of 0.05 at % to 25 at %, a content of the silicon in a range of 0.05 at % to 3 at %, a content of the copper in a range of 50 at % to 90 at %, and a content of the titanium in a range of 1 at % to 30 at %.

14. The printed wiring board according to claim 3, wherein the second resin insulating layer includes glass particles.

15. The printed wiring board according to claim 14, wherein the second resin insulating layer includes carbon, oxygen and silicon.

16. The printed wiring board according to claim 3, wherein the second conductor layer includes a plurality of conductor circuits including a smallest conductor circuit having a smallest width in a range of 1.5 μm to 5 μm.

17. The printed wiring board according to claim 4, wherein the second resin insulating layer includes glass particles.

18. The printed wiring board according to claim 17, wherein the second resin insulating layer includes carbon, oxygen and silicon.

19. The printed wiring board according to claim 4, wherein the second conductor layer includes a plurality of conductor circuits including a smallest conductor circuit having a smallest width in a range of 1.5 μm to 5 μm.

20. The printed wiring board according to claim 5, wherein the second conductor layer includes a plurality of conductor circuits including a smallest conductor circuit having a smallest width in a range of 1.5 μm to 5 μm.
